(19) United States
(12) Patent Application Publication
(10) Pub. No.: US 2022/0283894 A1
(43) Pub. Date: Sep. 8, 2022

(54) DETECTION METHOD AND SYSTEM APPLIED TO INTELLIGENT ANALYSIS AND DETECTION FOR FLASH, INTELLIGENT TERMINAL, AND COMPUTER-READABLE STORAGE MEDIUM

(71) Applicant: Shenzhen SanDiYiXin Electronic Co., Ltd, Shenzhen (CN)

(72) Inventors: Ruhong Zhang, Shenzhen (CN); Laisheng Hu, Shenzhen (CN); Xiangbin Chen, Shenzhen (CN); Hui Zhang, Shenzhen (CN)

(21) Appl. No.: 17/651,054

(22) Filed: Feb. 14, 2022

(30) Foreign Application Priority Data
Mar. 5, 2021 (CN) 202110247275.5

(51) Int. Cl. G06F 11/07

(52) U.S. Cl. CPC G06F 11/0793; G06F 11/0727; G06F 11/0751

(57) ABSTRACT

An intelligent terminal, and a computer-readable storage medium is provided. The detection method includes: obtaining a column set, a page set, and a block set, and presetting a bad column set, a bad page set, an error threshold, and an initial bad block template; alternately obtaining bad page elements and bad column elements from the block set in sequence based on the error threshold, and alternately updating the bad page set and the bad column set in sequence; based on the bad column sets and the bad page sets corresponding to different error thresholds, updating the error threshold, obtaining a final column set from the bad column sets, and obtaining a final page set from the bad page sets; and obtaining a final bad block template. The present invention can reduce the impact of a bad page on a subsequent operation of selecting a bad column element.

### TECHNICAL FIELD

The present invention relates to the technical field of flash analysis and detection methods, and in particular, to a detection method and system applied to intelligent analysis and detection for flash, an intelligent terminal, and a computer-readable storage medium.

### BACKGROUND

Flash, also referred to as flash memory, is a storage medium that allows repeated erasing or writing during operation. In addition, the flash can keep stored data information in the case of a power failure. The flash is mainly classified into NAND flash and NOR flash. Compared with the NOR flash, the NAND flash has the advantages of high erasing and writing speeds, a large storage capacity, and a low unit cost. Therefore, the NAND flash is applied more widely. Commonly used NAND flash products include flash disks, digital memory cards, and the like.

NAND flash may be physically divided into blocks, pages, columns, or physical cells (also referred to as cells). NAND flash consists of several blocks. Each block consists of several pages. Each page consists of several columns (or physical cells). For different types of flash, each column (physical cell) can store at least one bit of data. Therefore, there are three types of NAND flash addresses: block addresses corresponding to blocks; page addresses (also referred to as in-block page addresses) corresponding to pages; and column addresses (also referred to as in-page byte addresses) corresponding to columns (or physical cells).

During long-term usage of NAND flash, each block may have memory cells that fail to store data normally or read data correctly. To guarantee integrity of stored data, it is necessary to skip these abnormal memory cells during storage of the data. To find address information of these problematic memory cells, it is necessary to analyze and detect the NAND flash to find the bad page(s) and bad column(s) in the blocks.

With the development of the manufacturing process of flash, detection and analysis of bad pages and bad columns are also becoming more important. However, the inventor believes that analyzing bad pages and/or bad columns in a flash according to a detection and analysis method in the existing technology is poor in accuracy, which may lead to a decrease of the available capacity of the flash.

### SUMMARY

A first objective of the present invention is to provide a detection method applied to intelligent analysis and detection for flash. The detection method has the characteristic of increasing the available capacity of NAND flash after analysis and detection.

The first objective of the present invention is achieved via the following technical scheme:

a method including the following steps: step S1: obtaining a column set, a page set, and a block set including the column set and the page set, and presetting a bad column set, a bad page set, an error threshold that can be updated for each iteration, and an initial bad block template including the bad column set and the bad page set;

step S2: according to a bad page selection strategy and a bad column selection strategy, alternately obtaining bad page elements and bad column elements from the block set in sequence based on the error threshold, and alternately updating the bad page set and the bad column set in sequence;

step S3: based on the bad column sets and the bad page sets corresponding to different error thresholds, updating the error threshold according to a bad template iteration strategy, obtaining a final column set from the bad column sets, and obtaining a final page set from the bad page sets; and

step S4: obtaining a final bad block template by updating the initial bad block template based on the final column set and the final page set.

By adopting the above technical scheme, a column set contains all columns in a block, and a page set contains all pages in a block. A bad column set contains all columns that are rated as bad columns via instruction error correction. A bad page set contains all pages that are rated as bad pages via instruction error correction. An initial bad block template refers to a template obtained with reference to a bad column set and a bad page set. If the initial bad block template is used to analyze, read from, and write to all blocks in a flash, the available capacity of the flash can be evaluated.

The bad page selection strategy is a method of selecting the bad page elements from the page set based on the error threshold via instruction error correction, while the bad column selection strategy is a method of selecting the bad column elements from the column set based on the error threshold via instruction error correction. Selecting the bad page elements and/or the bad column elements is equivalent to an operation of selecting bad elements, while updating the bad page set and/or the bad column set based on the bad page elements is equivalent to an operation of updating a bad set. Step S2 is equivalent to alternately performing the operation of selecting bad elements and the operation of updating a bad set in sequence. When the bad page elements are selected from the page set based on the error threshold via instruction error correction, the bad column elements affect determining of the page set via instruction error correction. Therefore, if a relatively precise bad column set is obtained first, and then the page set is evaluated via instruction error correction, the accuracy of the instruction error correction can be improved. This makes the obtained bad page set more accurate. Similarly, when the bad column elements are selected from the column set based on the error threshold via instruction error correction, the bad page elements affect determining of the column set via instruction error correction. Therefore, if a relatively precise bad page set is obtained first, and then the column set is evaluated via instruction error correction, the accuracy of the instruction error correction can be improved. This makes the obtained bad column set more accurate.

The error threshold is a condition of evaluation in the instruction error correction, and is equivalent to a criterion for determining a column as a bad column and/or determining a page as a bad page. A change of the error threshold affects an error threshold of the number of bad columns and/or the number of bad pages. However, in an actual analysis and detection process, it is difficult to directly obtain a correct value based on the error threshold. In a manner of changing the error threshold, there may be a plurality of bad page sets and/or a plurality of bad column sets corresponding to different error thresholds. A final column set and/or a final page set are/is selected from the bad page sets and/or the bad column sets via screening, comparison, and determining, which is equivalent to selecting a relatively accurate error threshold from a plurality of error thresholds. Therefore, the bad block template obtained finally is more accurate.

In this manner of alternately performing operations of selecting bad elements and updating a bad set in sequence, the accuracy of the bad column set and/or the bad page set can be improved. After repeated iteration loops, the bad column set and/or the bad page set tend to be more accurate, thus making the bad block template more accurate. In addition, due to a physical property of NAND flash, some pages are bad pages inherently. Therefore, due to a manner of selecting bad page elements before selecting bad column elements, these bad pages may be selected from the block set first and taken as the bad page elements, to reduce the impact of these bad pages on a subsequent operation of selecting the bad column elements. This reduces generation of false bad columns, and makes the final bad block template more accurate, thereby increasing the available capacity of the NAND flash after analysis and detection.

Optionally, step S2 includes:

step S21: obtaining to-be-detected page subsets from the page set based on the bad column set according to a bad column interference elimination strategy, analyzing the to-be-detected page subsets in sequence based on the error threshold according to a bad page determining strategy, obtaining the bad page elements from the block set, and updating the bad page set based on the bad page elements; and

step S22: obtaining to-be-detected column subsets from the column set based on the bad page set according to a bad page interference elimination strategy, analyzing the to-be-detected column subsets in sequence based on the error threshold according to a bad column determining strategy, obtaining the bad column elements from the block set, and updating the bad column set based on the bad column elements.

By adopting the above technical scheme, during bad page interference elimination, when the instruction error correction needs to be performed on the page set, pages less affected by the bad column set are selected from the page set as the to-be-detected page subsets, then the to-be-detected page subsets are analyzed in sequence to obtain the bad page elements, and the bad page elements are updated to the bad page set. Therefore, a more precise bad page set is obtained. Similarly, during bad column interference elimination, when the instruction error correction needs to be performed on the column set, columns less affected by the bad page set are selected from the column set as the to-be-detected column subsets, then the to-be-detected column subsets are analyzed to obtain the bad column elements, and the bad column elements are updated to the bad column set. Therefore, a more precise bad column set is obtained.

Optionally, step S1 further includes: obtaining original column subsets and original page subsets, where the column set contains the original column subsets, and the page set contains the original page subsets;

step S21 includes:

step S211: obtaining interference page subsets by mapping the bad column set to the original page subsets;

step S212: obtaining complements of the interference page subsets within corresponding original page subsets in sequence, and generating the to-be-detected page subsets; and

step S213: according to the bad page determining strategy, analyzing the to-be-detected page subsets in sequence based on the error threshold, obtaining the bad page elements from the block set, and updating the bad page set based on the bad page elements; and

step S22 includes:

step S221: obtaining interference column subsets by mapping the bad page set to the original column subsets;

step S222: obtaining complements of the interference column subsets within corresponding original column subsets in sequence, and taking the complements as the to-be-detected column subsets; and

step S223: according to the bad column determining strategy, obtaining the bad column elements from the to-be-detected column subsets based on the error threshold, and updating the bad column set.

By adopting the above technical scheme, the original column subset contains memory cells in a same column, and the original page subset contains memory cells in a same page. After the bad column set is mapped to any original page subset, memory cells that may intersect with the bad column set may be obtained from the original page subset, while the interference column subset contains these memory cells. All the memory cells in the interference column subset have been determined as part of a bad page. The memory cells in the interference column subset are skipped during data storage. Therefore, when analysis and detection are performed to determine how many memory cells in the original page subset need to be skipped, a complement of the interference page subset within an original page subset is obtained as a to-be-detected page subset for analysis. This can reduce interference of the current bad page in analysis of a bad column. Similarly, when analysis and detection are performed to determine how many memory cells in the original column subset need to be skipped, a complement of the interference column subset within an original column subset is obtained as a to-be-detected column subset for analysis. This can reduce interference of the current bad column in analysis of a bad page.

Optionally, step S213 includes:

step S2131: obtaining page error values of the to-be-detected page subsets in sequence according to an instruction error correction strategy;

step S2132: based on the error threshold and the page error values, according to a bad page screening strategy, sequentially selecting, from the to-be-detected page subsets, those subsets not meeting a page validity condition as invalid page subsets; and

step S2133: obtaining bad page elements based on the original page subsets corresponding to the invalid page subsets, and obtaining a set containing all the bad page elements as the bad page set; and

step S223 includes:

step S2231: obtaining column error values of the to-be-detected column subsets in sequence according to the instruction error correction strategy;

step S2232: based on the error threshold and the column error values, according to a threshold comparison strategy, selecting, as an invalid column subset, to-be-detected column subsets that do not meet a column precision condition from the to-be-detected column subsets; and

step S2233: obtaining the bad column elements based on the original column subsets corresponding to the invalid column subsets, and obtaining a set containing all the bad column elements as the bad column set.

By adopting the above technical scheme, in the instruction error correction strategy, data may be first written into each memory cell of the to-be-detected column subset, and then read out for comparison. Subsequently, the number of erroneous bits is counted. A larger number of erroneous bits leads to a higher error value. When the error value is higher than the error threshold, the to-be-detected column subset does not meet a column precision condition. In this case, the to-be-detected column subset can be evaluated as an invalid column subset. At the same time, an original subset corresponding to the invalid column subset is taken as a bad column, and the bad column is recorded by including the bad page elements into the bad page set. After all the bad page elements are recorded, the current bad page set is equivalent to a bad column template recording bad columns. An old bad column template is replaced with the current bad column template, thereby completing update of a bad column template. Similarly, the invalid page subsets not meeting the page validity condition can be obtained by calculating a column error value of the to-be-detected column subsets and comparing the column error value with the error threshold, thereby obtaining a bad page template recording bad pages. An old bad page template is replaced with the current bad page template, thereby completing update of a bad page template.

Optionally, step S3 includes:

step S31: establishing a template library used for storing to-be-compared templates corresponding to different error thresholds;

step S32: according to a template comparison strategy, determining whether complete error thresholds in the current template library have a minimum value meeting an available capacity condition, and if yes, performing step S34, and if no, performing step S33;

step S33: updating the error thresholds, updating the to-be-compared template based on the bad column set and the bad page set, storing the updated error thresholds and updated to-be-compared template into the template library, and returning to step S2; and

step S34: generating the final column set and the final page set based on the determining result.

By adopting the above technical scheme, the to-be-compared template is the last bad column set and/or bad page set of the current bad column set and/or bad page set. The template library may store bad column sets and/or bad page sets corresponding to different error thresholds. A relatively proper error threshold can be found by comparing a plurality of bad column sets and/or bad page sets corresponding to different error thresholds. A bad column set and/or a bad page set corresponding to this error threshold needs to be relatively accurate and to meet an available capacity requirement for flash.

Optionally, step S32 includes:

step S321: determining whether the to-be-compared template exists in the current template library, and if yes, performing step S322, and if no, performing step S323;

step S322: determining whether the to-be-compared template meets an iteration termination condition, and if yes, performing step S34, and if no, performing step S33; and

step S323: obtaining a to-be-compared template containing the current bad column set and the current bad page set, and storing the to-be-compared template into the template library; and

step S34 further includes: obtaining the bad column set in the to-be-compared template as the final column set, and obtaining the bad page set in the to-be-compared template as the final page set.

By adopting the above technical scheme, the final column set and/or the final page set refer/refers to a bad column set and/or a bad page set that are/is relatively precise and can meet the available capacity requirement of the flash. To obtain the final column set and/or the final page set, it is necessary to update the error threshold, so that update and iteration are constantly performed on bad column sets and/or bad page sets. When the final column set and/or the final page set are not successfully selected, the current bad column set and/or bad page set are stored in the template library as to-be-compared templates. In other words, the template library stores candidate templates of the final column set and/or the final page set. As the error threshold changes, iteration and update are constantly performed on bad column sets and/or bad page sets until the final column set and/or the final page set appear/appears, thereby selecting a required final column set and/or a required final page set. When there is no to-be-compared template in the template library, the current bad column set and the current bad page set are added into the template library as to-be-compared templates.

Optionally, step S322 includes:

step S3221: presetting a column validity threshold, determining, based on the column validity threshold, whether the bad column set in the current to-be-compared template meets the available capacity condition, and if yes, performing step S3222, and if no, performing step S33; and

step S3222: presetting a column iteration threshold, analyzing the to-be-compared template and the bad column set based on the column iteration threshold, determining whether the to-be-compared template meets a capacity change condition, and if yes, performing step S3223, and if no, performing step S33; and

step S3223: presetting a page validity threshold, determining, based on the page validity threshold, whether the bad page set in the current to-be-compared template meets the available capacity condition, and if yes, performing step S3224, and if no, performing step S33; and

step S3224: presetting a page iteration threshold, analyzing the to-be-compared template and the bad page set based on the page iteration threshold, determining whether the to-be-compared template meets the capacity change condition, and if yes, performing step S34, and if no, performing step S33.

By adopting the above technical scheme, an error threshold corresponding to the current bad column set and/or bad page set is equivalent to an updated value of the error threshold corresponding to the to-be-compared template stored in the template library. By comparing the current bad column set and/or bad page set with the current to-be-compared template, it can be evaluated whether a change of the error threshold has an enough impact on generation of the current bad column set and/or bad page set. If the impact is relatively small, it indicates that update and iteration of the current bad column set and/or bad page set cause a relatively small change of precision. In addition, if the error threshold is too small, there may be too many bad column sets and/or bad page sets, which directly affects the available capacity of the flash after an entire analysis and detection process is completed. Therefore, the final column set and/or the final page set equivalently achieve/achieves balance between the accuracy of the bad column set and/or the bad page set and the available capacity of the flash. A bad block template that is relatively precise and meets the available capacity requirement can be obtained based on the final column set and the final page set.

A second objective of the present invention is to provide a detection system applied to intelligent analysis and detection for flash. The detection method has the characteristic of increasing the available capacity of NAND flash after analysis and detection.

The second objective of the present invention is achieved via the following technical scheme:

A detection system applied to intelligent analysis and detection for flash, including:

an initial template establishment module, configured to obtain a column set, a page set, and a block set including the column set and the page set, and preset a bad column set, a bad page set, an error threshold that can be updated for each iteration, and an initial bad block template including the bad column set and the bad page set;

a template update module, configured to: according to a bad page selection strategy and a bad column selection strategy, alternately obtain bad page elements and bad column elements from the block set in sequence based on the error threshold, and alternately update the bad page set and the bad column set in sequence;

a template iteration module, configured to: based on the bad column sets and the bad page sets corresponding to different error thresholds, update the error threshold according to a bad template iteration strategy, obtain a final column set from the bad column sets, and obtain a final page set from the bad page sets; and

a final template generation module, configured to obtain a final bad block template by updating the initial bad block template based on the final column set and the final page set.

A third objective of the present invention is to provide an intelligent terminal, having the characteristic of increasing the available capacity of NAND flash after analysis and detection.

The third objective of the present invention is achieved via the following technical scheme:

an intelligent terminal including a memory and a processor, where the memory stores a computer program which can be loaded and executed by the processor to implement the above detection method.

A fourth objective of the present invention is to provide a computer storage medium, which can store a corresponding program and has the characteristic of conveniently increasing the available capacity of NAND flash after analysis and detection.

The fourth objective of the present invention is achieved via the following technical scheme:

a computer-readable storage medium storing a computer program, where the computer program can be loaded and executed by the processor to implement the above detection method.

### BRIEF DESCRIPTION OF DRAWINGS

FIG. 1 is a flowchart of a detection method according to the present application;

FIG. 2 is a flowchart of an interference elimination step in a detection method according to the present application;

FIG. 3 is a flowchart of a step of obtaining a bad page set in a detection method according to the present application;

FIG. 4 is a flowchart of a step of obtaining a bad column set in a detection method according to the present application;

FIG. 5 is a flowchart of updating a column set and updating a page set in a detection method according to the present application;

FIG. 6 is a flowchart of a step of obtaining a to-be-compared template in a detection method according to the present application;

FIG. 7 is a flowchart of a step of obtaining a final column set and a step of obtaining a final page set in a detection method according to the present application; and

FIG. 8 is a structural block diagram of a detection system according to the present disclosure.

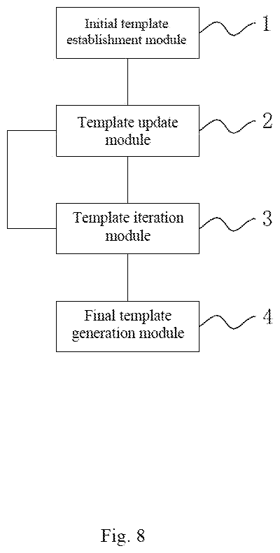

List of reference numerals in the drawings: 1—initial template establishment module; 2—template update module; 3—template iteration module; and 4—final template generation module.

### DETAILED DESCRIPTION

In the existing technology, a method for detecting and analyzing a flash is as follows:

extracting a block from blocks in a flash as a template block, and presetting a bad block template based on the template block;

extracting a template block, analyzing all columns in the template block via error correction based on an error correction code (ECC), and obtaining bad columns;

mapping the bad columns to all pages, and obtaining, from all the pages, the to-be-detected pages that are not affected by these bad columns;

analyzing all to-be-detected pages in the template block via error correction based on the ECC, and obtaining the bad pages;

updating the bad block template of the template block based on the bad columns and the bad pages; and

obtaining the available capacity of the flash by using the bad block template to analyze, read from, write to, and compare each block in the flash.

Further, in the method for detecting and analyzing a flash, a plurality of blocks may be alternatively extracted as template blocks. Finally, a plurality of bad block templates can be obtained. The plurality of bad block templates are used to analyze, read from, write to, and compare each block in the flash, thereby obtaining a more precise available capacity of the flash.

In view of the above existing technology, the inventor believes that during obtaining of a bad column according to the above detection and analysis method, all pages are taken as good pages, that is, the impact of a bad page on a bad column is ignored. However, due to a physical property of NAND flash, some pages are bad pages inherently. If the impact of these bad pages on error correction-based analysis of each column is not reduced, false bad columns may appear among these columns. In addition, bad columns and bad pages influence each other. The error correction capability of ECC error correction—based analysis is reduced due to these false bad columns, which affects analysis of the pages in the next step, and finally obtains more bad pages. Therefore, the available capacity of the NAND flash after analysis and detection is greatly reduced.

To make the objectives, technical schemes, and advantages of the present application clearer, the following clearly and completely describes the technical schemes in the embodiments of the present application with reference to the accompanying drawings in the embodiments of the present application. Apparently, the described embodiments are merely some rather than all of the embodiments of the present application. All other embodiments obtained by those of ordinary skill in the art based on the embodiments of the present application without inventive effort are within the scope of the present application.

In addition, the term “and/or” in this specification is merely an association relationship that describes associated objects, and represents that there may be three kinds of relationships. For example, A and/or B may represent three cases: only A exists, both A and B exist, and only B exists. In addition, unless otherwise specified, the slash “/” in this specification generally indicates that associated objects are in an “or” relationship.

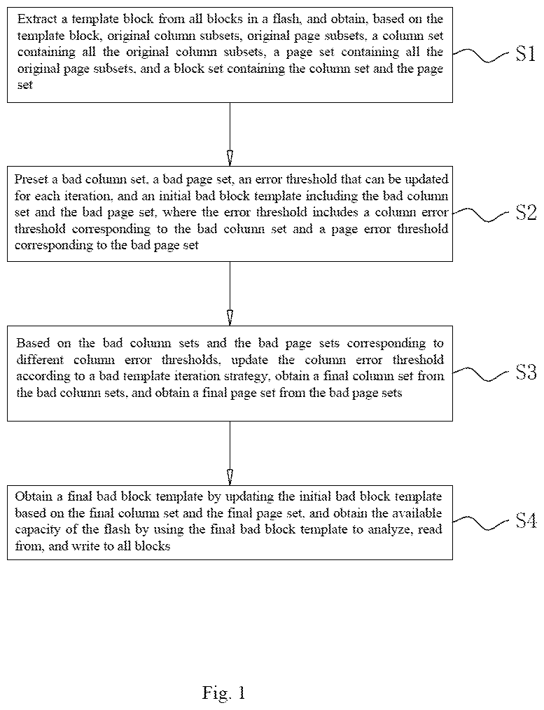

The embodiments of the present application are further described below in detail with reference to this specification and FIGS. 1 to 6.

### Embodiment I

An embodiment of the present application provides a detection method applied to intelligent analysis and detection for flash. A main process of the method is described as follows.

Referring to FIG. 1, at step S1, a template block is extracted from all blocks of flash. Original column subsets, original page subsets, a column set containing all the original column subsets, a page set containing all the original page subsets, and a block set containing the column set and the page set are obtained based on the template block. A bad column set, a bad page set, an error threshold that can be updated for each iteration, and an initial bad block template including the bad column set and the bad page set are preset. The error threshold includes a column error threshold corresponding to the bad column set and a page error threshold corresponding to the bad page set.

NAND flash may be physically divided into blocks, pages, and columns. The NAND flash is composed of a plurality of blocks. Each block is composed of a plurality of pages. Each page is composed of a plurality of columns. Any memory cell in each column is associated with one of the pages. There are three types of NAND flash addresses: block addresses corresponding to the blocks, page addresses corresponding to the pages, and column addresses corresponding to the columns. For a same block, pages and columns equivalently form a matrix, and the page addresses and the column addresses jointly determine addresses of all memory cells in the same block, where the page addresses are equivalent to X coordinates in a coordinate system, and column addresses are equivalent to Y coordinates in the coordinate system.

At step S1, one original column subset refers to one column. Each element in the original column subset can represent the position of each memory cell in a column. One original page subset refers to one page. Each element in the original page subset can represent the position of each memory cell in a page. The column set refers to a set containing all the original column subsets, thereby equivalently containing all the columns. The page set refers to a set containing all the original page subsets, thereby equivalently containing all the pages. The block set refers to a set containing all the columns and all the pages, thereby equivalently containing all memory cells in the template block.

The bad column set refers to a set containing all bad columns. When columns corresponding to any original column subset are evaluated as bad columns, a bad column element may be generated based on the original column subset and added to the bad column set. The bad page set refers to a set containing all bad pages. When a page corresponding to any original page subset is evaluated as a bad page, a bad page element may be generated based on the original page subset and added to the bad page set. The bad column set is equivalent to a bad column template in which all bad columns are marked. All memory cells on these columns in the bad column template are skipped during data storage of the flash. Similarly, the bad page set is equivalent to a bad page template in which all bad pages are marked. All memory cells on these pages in the bad page template are skipped during data storage of the flash. Therefore,

in this embodiment, an initial set of the bad page set and an initial set of the bad column set are both empty sets. The bad page set and/or the bad column set need/needs to be refined gradually by extracting a bad page element and/or a bad column element and performing update and iteration. In other embodiments, if individual bad pages and/or bad columns can be determined before analysis and detection, corresponding bad page elements and/or bad column elements can be added to the bad page set and/or the bad column set in advance.

The initial bad block template containing the bad column set and the bad page set is equivalent to the initial bad block template containing the bad column template and the bad page template. If the initial bad block template is used to analyze, read from, and write to all blocks in the flash, the available capacity of the flash can be estimated. The error threshold is one of conditions for evaluating a bad column and/or a bad page in the instruction error correction, and is equivalent to a criterion for determining a column as a bad column and/or determining a page as a bad page. A value of the error threshold directly affects the number of elements in the bad column set and/or the bad page set.

It should be noted that, the error threshold is not a definite absolute value, and there is no absolute limit for a bad column and/or a bad page. A larger error threshold leads to stricter evaluation of the bad column and/or the bad page. Finally, the number of bad columns and/or bad pages becomes smaller, and the available capacity of the flash after analysis and detection becomes larger. Otherwise, the number of bad columns and/or bad pages becomes larger, and the available capacity of the flash after analysis and detection becomes smaller.

Specifically, the error threshold includes the page error threshold for evaluating a bad page and the column error threshold for evaluating a bad column. In this embodiment, data is first written into all pages via ECC-based instruction error correction, and then read out for comparison. In addition, the number of erroneous bits on each page is counted, and an average value of the numbers of erroneous bits on all the pages is taken as an initial page error threshold. Similarly, the number of erroneous bits in each column is counted via ECC-based instruction error correction, and an average value of the numbers of erroneous bits in all the columns is taken as an initial column error threshold.

Referring to FIG. 1, at step S2, according to a bad page selection strategy and a bad column selection strategy, bad page elements and bad column elements are alternately obtained from the block set in sequence based on the error threshold, and the bad page set and the bad column set are alternately updated in sequence.

The bad page selection strategy is a method for obtaining bad page elements from the block set, and replacing the bad page set with a set containing all bad page elements, namely, updating the bad page set, which is equivalent to updating the bad page template. The bad column selection strategy is a method for obtaining bad column elements from the block set, and replacing the bad column set with a set containing all bad column elements, namely, updating the bad column set, which is equivalent to updating the bad column template. Therefore, a more precise bad page template and/or bad column template are/is obtained.

Specifically, because the bad page selection strategy and the bad column selection strategy are performed alternatively in sequence, the bad page set and the bad column set are also updated alternatively in sequence. In other words, the following order is formed: first, selecting a bad page and updating the bad page template; and then, selecting a bad column based on the current bad page template and updating the bad column template. It should be noted that, due to a physical property of NAND flash, some pages are bad pages inherently. Therefore, to update the bad page template first, these pages that are bad pages inherently may be screened out first, which reduces the impact of these pages on updating of the bad column template, and improves the precision of the bad column template.

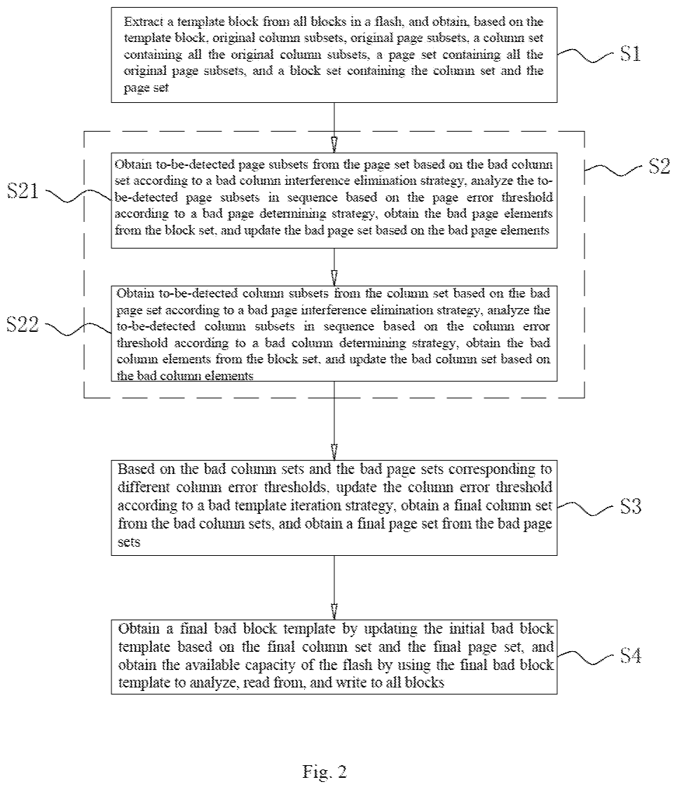

Referring to FIG. 2, step S2 includes:

step S21: obtaining to-be-detected page subsets from the page set based on the bad column set according to a bad column interference elimination strategy, analyzing the to-be-detected page subsets in sequence based on the page error threshold according to a bad page determining strategy, obtaining the bad page elements from the block set, and updating the bad page set based on the bad page elements.

The bad column interference elimination strategy refers to a method of reducing interference of the current bad column in evaluation of a bad page in this step. The to-be-detected page subset refers to a set of memory cells, on which error correction instruction detection needs to be performed, in a corresponding page set. The bad page determining strategy refers to a method of evaluating whether a page corresponding to a to-be-detected page subset is a bad page by reading from, writing to, and detecting the error number of the to-be-detected page subset and comparing the error number with the page error threshold.

Because all memory cells in each bad column in the bad column set have been evaluated as memory cells that need to be skipped during data storage. If these memory cells still participate in analysis of a page, accuracy of an analysis result is affected. As a result, there may be too many bad pages. Therefore, it is necessary to first extract to-be-detected page subsets from each page set to reduce the impact of the current bad column on the page set, and then update the bad page template.

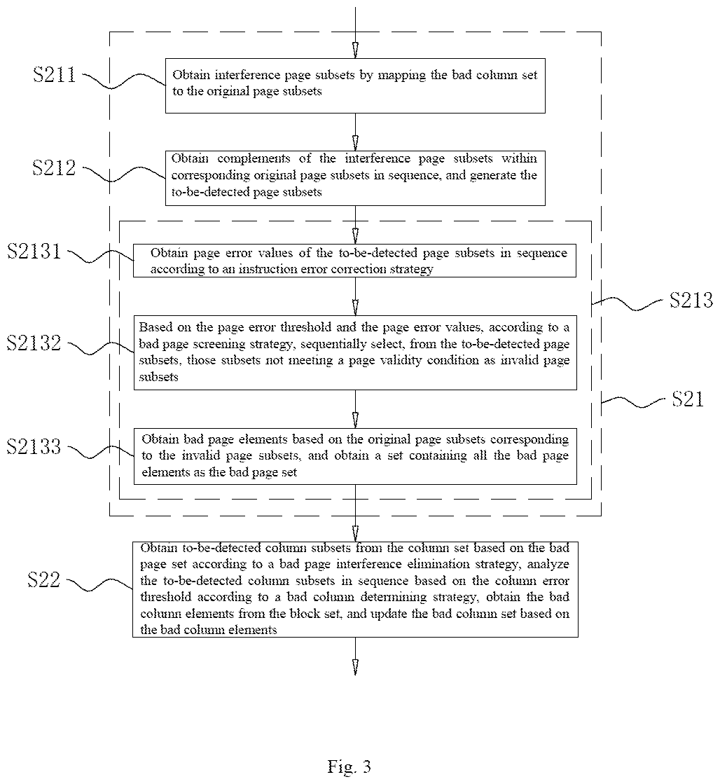

Referring to FIG. 3, step S21 includes the following steps.

At step S211, interference page subsets are obtained by mapping the bad column set to the original page subsets.

An intersection between the bad column set and the original subset can be obtained by mapping the bad column set to the original page subset, which is equivalent to obtaining an overlapped memory cell between the bad column and the page. Each original page subset is correspondingly provided with an interference page subset. The interference page subset contains all memory cells that are in the original page subset and overlapped with memory cells in the current bad column.

At step S212, complements of the interference page subsets within corresponding original page subsets are obtained in sequence, and the to-be-detected page subsets are generated.

Each original page subset is correspondingly provided with an interference page subset. For any original page subset, the interference page subset contains memory cells that are in the original page subset and overlapped with memory cells in the current bad column. Therefore, the complement of the interference page subset within the original page subset, namely, the interference page subset, contains all memory cells that are less affected by the current bad column and need to participate in page analysis.

At step S213, according to the bad page determining strategy, the to-be-detected page subsets are analyzed in sequence based on the page error threshold, the bad page elements are obtained from the block set, and the bad page set is updated based on the bad page elements.

The bad page determining strategy refers to a method of evaluating the damage degree of a page corresponding to a to-be-detected page subset by analyzing memory cells in the to-be-detected page subset. If the damage degree of the page reaches a degree corresponding to the page error threshold, it is necessary to evaluate the page as a bad page, generate bad page elements based on the page, and record them in the bad page set.

Referring to FIG. 3, step S213 includes the following steps.

At step S2131, page error values of the to-be-detected page subsets are obtained in sequence according to an instruction error correction strategy.

The instruction error correction strategy refers to the following method: based on ECC-based instruction error correction, first writing data into each memory cell of the to-be-detected page subset, then reading out the data for comparison, and counting the number of erroneous bits. A larger absolute value of a bit number calculated via ECC-based instruction error correction leads to a larger page error value of the to-be-detected page subset.

At step S2132, based on the page error threshold and the page error values, according to a bad page screening strategy, those subsets not meeting a page validity condition among the to-be-detected page subsets are sequentially selected as invalid page subsets.

The bad page screening strategy is a method of determining whether a to-be-detected page subset meets the page validity condition by comparing a page error value with the page error threshold. If the page error value of the to-be-detected page subset is greater than or equal to the page error threshold, the to-be-detected page subset can be determined as the invalid page subset.

At step S2133, bad page elements are obtained based on the original page subsets corresponding to the invalid page subsets, and a set containing all the bad page elements is obtained as the bad page set.

None of to-be-tested page subsets corresponding to the invalid page subsets meet the page validity condition. Therefore, pages corresponding to the invalid page subsets can be evaluated as bad pages. Obtaining each bad page element based on each bad page is equivalent to marking each bad page with each bad page element. After the bad page set is reset to an empty set, adding all obtained bad page elements into the bad page set is equivalent to making the current bad page set contain all the bad pages and completing update of the bad page template.

It should be noted that, in the current step, pages that are not bad pages are evaluated as good pages, and the number of good pages should be at least 30% of the total number of pages.

At step S22, to-be-detected column subsets are obtained from the column set based on the bad page set according to a bad page interference elimination strategy, the to-be-detected column subsets are analyzed in sequence based on the column error threshold according to a bad column determining strategy, the bad column elements are obtained from the block set, and the bad column set is updated based on the bad column elements.

The bad page interference elimination strategy refers to a method of reducing interference of the current bad page to evaluation of a bad column in this step. The to-be-detected column subset refers to a set of memory cells, on which error correction instruction detection needs to be performed, in a corresponding column set. The bad column determining strategy refers to a method of evaluating whether a column corresponding to a to-be-detected column subset is a bad column by reading from, writing to, and detecting the error number of the to-be-detected column subset and comparing the error number with the column error threshold.

Because all memory cells in each bad page in the bad page set have been evaluated as memory cells that need to be skipped during data storage. If these memory cells still participate in analysis of a column, accuracy of an analysis result is affected. As a result, there may be too many bad columns. In other words, a false bad column is generated. Therefore, it is necessary to first extract to-be-detected column subsets from the column sets to reduce the impact of the current bad page on the column sets, and then update the bad column template.

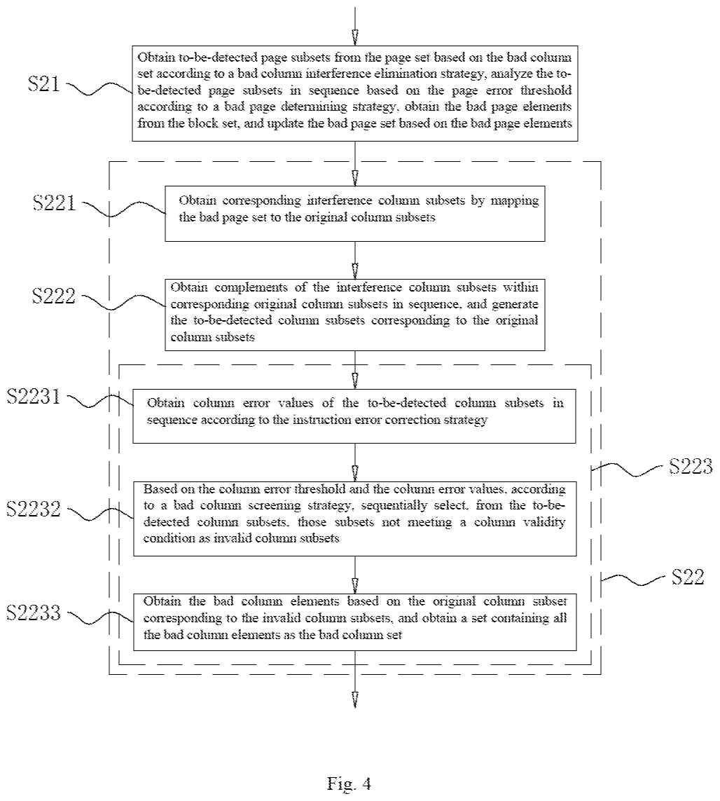

Referring to FIG. 4, step S22 includes the following steps.

At step S221, corresponding interference column subsets are obtained by mapping the bad page set to the original column subsets.

An intersection between the bad page set and the original subset can be obtained by mapping the bad page set to the original column subset, which is equivalent to obtaining an overlapped memory cell between the bad page and the column. Each original column subset is correspondingly provided with an interference column subset. The interference column subset contains all memory cells that are in the original column subset and overlapped with memory cells in the current bad page.

At step S222, complements of the interference column subsets within corresponding original column subsets are obtained in sequence, and the to-be-detected column subsets corresponding to the original column subsets are generated.

Each original column subset is correspondingly provided with an interference column subset. For any original column subset, the interference column subset contains memory cells that are in the original column subset and overlapped with memory cells in the current bad page. Therefore, the complement of the interference column subset within the original column subset, namely, the interference column subset, contains all memory cells that are less affected by the current bad page and need to participate in column analysis.

At step S223, the to-be-detected column subsets are analyzed in sequence based on the column error threshold according to the bad column determining strategy, the bad column elements are obtained from the block set, and the bad column set is updated based on the bad column elements.

The bad column determining strategy refers to a method of evaluating the damage degree of a column corresponding to a to-be-detected column subset by analyzing memory cells in the to-be-detected column subset. If the damage degree of the column reaches a degree corresponding to the column error threshold, it is necessary to evaluate the column as a bad column, generate bad column elements based on the column, and record them in the bad column set.

Referring to FIG. 4, step S223 includes the following steps.

At step S2231, column error values of the to-be-detected column subsets are obtained in sequence according to the instruction error correction strategy.

The instruction error correction strategy refers to the following method: based on ECC-based instruction error correction, first writing data into each memory cell of the to-be-detected column subset, then reading out the data for comparison, and counting the number of erroneous bits. A larger absolute value of a bit number calculated via ECC-based instruction error correction leads to a larger column error value of the to-be-detected column subset.

At step S2232, based on the column error threshold and the column error values, according to a bad column screening strategy, those subsets not meeting a column validity condition among the to-be-detected column subsets are sequentially selected as invalid column subsets

The bad column screening strategy is a method of determining whether a to-be-detected column subset meets the column validity condition by comparing a column error value with the column error threshold. If the column error value of the to-be-detected column subset is greater than or equal to the column error threshold, the to-be-detected column subset can be determined as the invalid column subset.

At step S2233, the bad column elements are obtained based on the original column subsets corresponding to the invalid column subsets, and a set containing all the bad column elements is obtained as the bad column set.

None of to-be-tested column subsets corresponding to the invalid column subsets meet the column validity condition. Therefore, columns corresponding to the invalid column subsets can be evaluated as bad columns. Obtaining each bad column element based on each bad column is equivalent to marking each bad column with each bad column element. After the bad column set is reset to an empty set, adding all obtained bad column elements into the bad column set is equivalent to making the current bad column set contain all the bad columns and completing update of the bad column template.

It should be noted that, in the current step, columns that are not bad columns are evaluated as good columns, and the number of good columns should be at least 30% of the total number of columns.

At step S3, based on the bad column sets and the bad page sets corresponding to different column error thresholds, the column error threshold is updated according to a bad template iteration strategy, a final column set is obtained from the bad column sets, and a final page set is obtained from the bad page sets.

In a manner of changing the error threshold, there may be a plurality of bad page sets and/or a plurality of bad column sets corresponding to different error thresholds. Via screening, comparison, and determining, the following manner may be used: selecting an error threshold meeting requirements from a plurality of error thresholds, obtaining the bad page set corresponding to the page error threshold as the final page set, and obtaining the bad column set corresponding to the column error threshold as the final column set. Therefore, the bad block template obtained finally is more accurate.

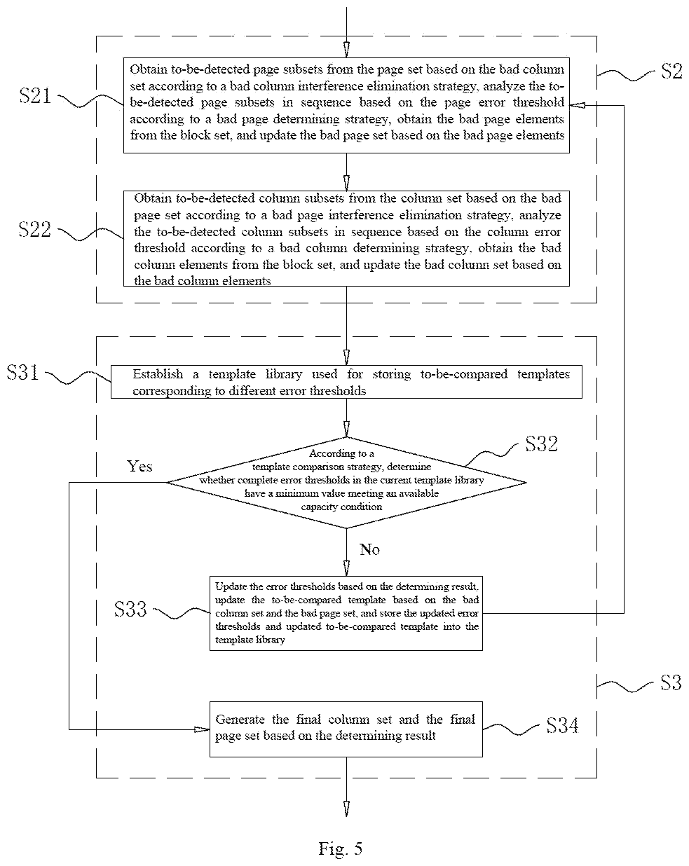

Referring to FIG. 5, step S3 includes the following steps.

At step S31, a template library used for storing to-be-compared templates corresponding to different error thresholds is established.

The to-be-compared template is a bad page template and/or a bad column template corresponding to the current bad page template and/or bad column template before updating. The to-be-compared template stored in the template library is used for comparison with the current bad page template and/or bad column template. It should be noted that, the to-be-compared template is equivalent to a candidate template of a final bad block template. When the to-be-compared template meets a demand condition, the final bad block template can be obtained from the to-be-compared template.

At step S32, according to a template comparison strategy, it is determined whether complete error thresholds in the current template library have a minimum value meeting an available capacity condition; and if yes, step S34 is performed, and if no, step S33 is performed.

The template comparison strategy refers to a method of comparing the current bad page template and/or bad column template with the last bad page template and/or bad column template, to evaluate the influence degree of an updated error threshold. A larger error threshold leads to a smaller available capacity after analysis and detection for flash. However, a larger error threshold leads to smaller precision of a bad page template and/or a bad column template. Therefore, it is necessary to select the minimum error threshold that meets the available capacity. If this error threshold cannot be selected in the current step, the error threshold should be updated continuously for iteration until the minimum error threshold meeting the available capacity condition is successfully selected. It should be noted that, the complete error thresholds in the current template library have the minimum value meeting the available capacity condition, which means that there are simultaneously the minimum column error threshold meeting the available capacity condition and the minimum page error threshold meeting the available capacity condition.

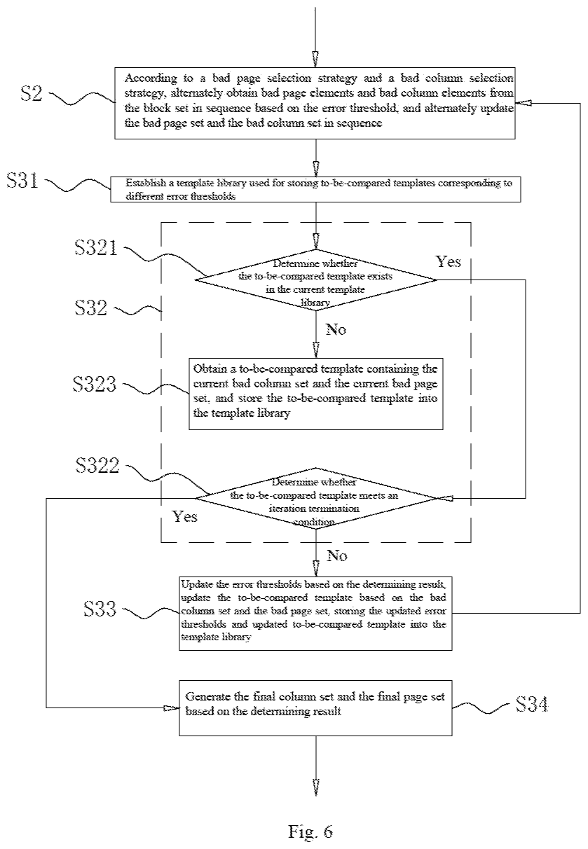

Referring to FIGS. 5 and 6, in step S3, step S32 includes the following steps.

At step S321, it is determined whether the to-be-compared template exists in the current template library, and if yes, step S322 is performed, and if no, step S323 is performed.

If there is no to-be-compared template in the current template library, it indicates that the error threshold in the current bad page template and/or bad column template has not been updated, and no template in the template library supports comparison. Therefore, it is impossible to determine whether the demand condition is met. If there is a to-be-compared template in the current template library, it is necessary to compare the current bad page template and/or bad column template with the current to-be-compared template for analysis.

At step S322, it is determined whether the to-be-compared template meets an iteration termination condition, and if yes, step S34 is performed, and if no, step S33 is performed.

When both the bad column set in the to-be-compared template and the bad page set in the to-be-compared template meet the iteration termination condition, the minimum error threshold meeting the available capacity appears. Therefore, update of the error threshold can be stopped, and the final column set and/or the final page set can be selected based on a determining result.

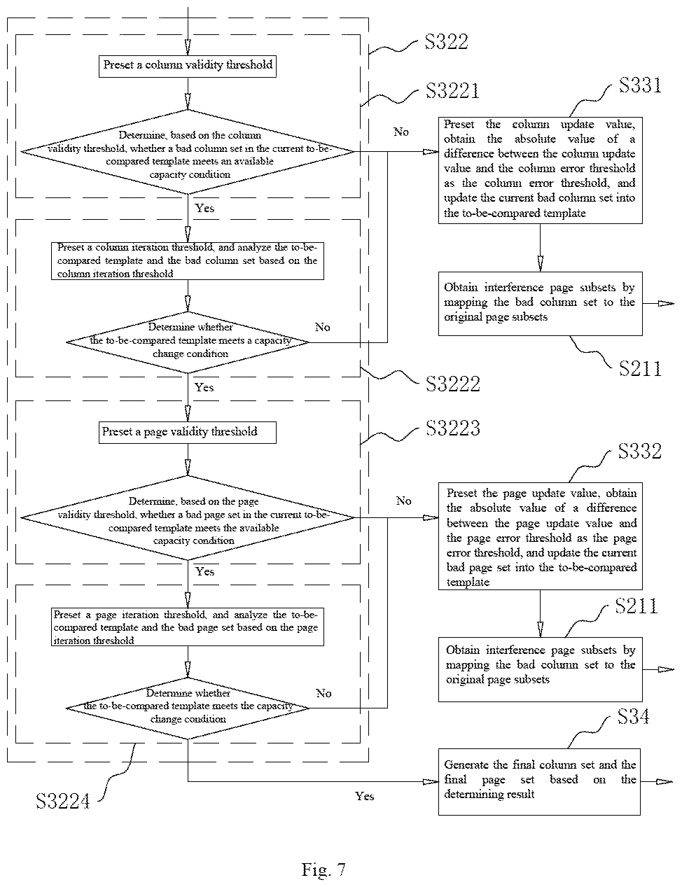

Referring to FIG. 6 and FIG. 7, step S322 includes the following steps.

At step S3221, a column validity threshold is preset, it is determined based on the column validity threshold whether the bad column set in the current to-be-compared template meets the available capacity condition, and if yes, step S3222 is performed, and if no, step S331 is performed.

A larger number of bad columns leads to a larger number of columns that need to be skipped during data storage in each column. Therefore, it is necessary to limit the total number of bad columns. The column validity threshold refers to the maximum number of bad columns. When the number of elements in the bad column set is greater than or equal to the column validity threshold, it is indicated that there are too many current bad columns, and the available capacity of the columns cannot meet the demand. Therefore, it is necessary to decease the value of the column error threshold and update the bad column template for iteration.

At step S3222, a column iteration threshold is preset, the to-be-compared template and the bad column set are analyzed based on the column iteration threshold, it is determined whether the to-be-compared template meets a capacity change condition, and if yes, step S3223 is performed, and if no, step S331 is performed.

The bad column set in the to-be-compared template is the last bad column set of the current bad column set. When the column error threshold changes, the difference between the total number of elements in the current bad column set and the total number of elements in the last bad column set can reflect the impact of the change of the column error threshold on the last bad column set. A smaller impact leads to a smaller significance of the change of the column error threshold to update and iteration of the to-be-compared template, and the column error threshold needs to be updated. On the contrary, a larger impact leads to a larger significance of the change of the column error threshold to update and iteration of the to-be-compared template. The column iteration threshold refers to the minimum value of a number change before and after update of the bad column set. To make the finally obtained bad column template more accurate and less affected by a change of the column error threshold, it is necessary to select, as a bad column template, a to-be-compared template whose number change before and after update of the bad column set is less than the column iteration threshold. Therefore, if the number change before and after update of the bad column set is less than the column iteration threshold, the current to-be-compared template meets the capacity change condition.

Specifically, the to-be-compared template and the bad column set are analyzed based on the column iteration threshold, it is determined whether the to-be-compared template meets a capacity change condition, and if yes, step S3223 is performed, and if no, step S331 is performed. Step S331 includes:

obtaining the absolute value of a difference between the total amount of elements in the bad column set in the to-be-compared template and the total amount of elements in the current bad column set as a column comparison value, comparing the column comparison value with the column iteration threshold, and if the column comparison value is less than the column iteration threshold, performing step S3223, if the column comparison value is greater than or equal to the column iteration threshold, performing step S331.

At step S3223, a page validity threshold is preset, it is determined based on the page validity threshold whether the bad page set in the current to-be-compared template meets the available capacity condition, and if yes, step S3224 is performed, and if no, step S332 is performed.

In this case, a relatively accurate bad column template has been obtained, and it is necessary to select a relatively accurate bad page template. A larger number of bad pages leads to a larger number of pages that need to be skipped during data storage in each page. Therefore, it is necessary to limit the total number of bad pages. The page validity threshold refers to the maximum number of bad pages. When the number of elements in the bad page set is greater than or equal to the page validity threshold, there are too many current bad pages, and the available capacity of the pages cannot meet the demand. Therefore, it is necessary to decease the value of the page error threshold and update the bad page template for iteration.

At step S3224, a page iteration threshold is preset, the to-be-compared template and the bad page set are analyzed based on the page iteration threshold, it is determined whether the to-be-compared template meets the capacity change condition, and if yes, step S34 is performed, and if no, step S332 is performed.

The bad page set in the to-be-compared template is the last bad page set of the current bad page set. When the page error threshold changes, the difference between the total number of elements in the current bad page set and the total number of elements in the last bad page set can reflect the impact of a change of the page error threshold on the last bad page set. The page iteration threshold refers to the minimum value of a number change before and after update of the bad page set. To make the finally obtained bad page template more accurate and less affected by a change of the page error threshold, it is necessary to select, as a bad page template, a to-be-compared template whose number change before and after update of the bad page set is less than the page iteration threshold. Therefore, if the number change before and after update of the bad page set is less than the page iteration threshold, the current to-be-compared template meets the capacity change condition.

Specifically, the to-be-compared template and the bad page set are analyzed based on the page iteration threshold, it is determined whether the to-be-compared template meets the capacity change condition, and if yes, step S34 is performed, and if no, step S332 is performed. Step S332 includes:

obtaining the absolute value of a difference between the total amount of elements in the bad page set in the to-be-compared template and the total amount of elements in the current bad page set as a page comparison value, comparing the page comparison value with the page iteration threshold, and if the page comparison value is less than the page iteration threshold, performing step S34, if the page comparison value is greater than or equal to the page iteration threshold, performing step S332.

At step S323, a to-be-compared template containing the current bad column set and the current bad page set is obtained, and is stored into the template library.

In this case, there is no to-be-compared template in the current template library, the current bad page template is a bad page template obtained via the first update, and the current bad column template is a bad column template also obtained via the first update. Therefore, it is necessary to add the current bad page template and the current bad column template to the template library as to-be-compared templates.

Referring to FIG. 6, at step S33, the error threshold is updated based on the determining result, the to-be-compared template is updated based on the bad column set and the bad page set, an updated error threshold and an updated to-be-compared template is stored into the template library, and step S2 is performed.

Because the error threshold includes the column error threshold and the page error threshold, it is necessary to determine, based on the determining result, whether the current column error threshold is not the minimum value meeting the available capacity condition, or the page error threshold is not the minimum value meeting the available capacity condition. However, after updating the column error threshold and/or page error threshold, it is necessary to store both the current bad column set and the current bad page set into the template library as new to-be-compared templates. At this time, the old to-be-compared templates are replaced with the current bad column set and the current bad page set.

Referring to FIG. 6 and FIG. 7, step S33 includes the following steps.

At step S331, the column update value is preset, the absolute value of the difference between the column update value and the column error threshold is obtained as the column error threshold, the current bad column set is updated into the to-be-compared template, and S211 is performed.

The process of updating the column error threshold is the process of gradually decreasing the column error threshold. The column update value refers to a value that needs to be subtracted each time the column error threshold is updated. When the column error threshold is updated, the current bad column set is used to replace the bad column set in the to-be-compared template, which is equivalent to taking the current bad column template as a new to-be-compared template, and waiting for comparison with a subsequently updated bad column template. Both the column error threshold and the bad column template are constantly updated until a relatively accurate bad column template meeting the requirement appears.

At step S332, the page update value is preset, the absolute value of the difference between the page update value and the page error threshold is obtained as the page error threshold, the current bad page set is updated into the to-be-compared template, and S211 is performed.

In this case, a relatively accurate bad column template has been obtained, and it is necessary to select a relatively accurate bad page template by updating the page error threshold. The page update value refers to a value that needs to be subtracted each time the page error threshold is updated. When the page error threshold is updated, the current bad page set is used to replace the bad page set in the to-be-compared template, which is equivalent to taking the current bad page template as a new to-be-compared template, and waiting for comparison with a subsequently updated bad page template.

At step S34, the final column set and the final page set are generated based on the determining result.

In this case, the column error threshold corresponding to the bad column set in the to-be-compared template is the minimum value meeting the available capacity condition. Therefore, the bad column set in the to-be-compared template is obtained as the final column set. In addition, the page error threshold corresponding to the bad page set in the to-be-compared template is the minimum value meeting the available capacity condition. Therefore, the bad page set in the to-be-compared template is obtained as the final page set.

At step S4, a final bad block template is obtained by updating the initial bad block template based on the final column set and the final page set, and the available capacity of the flash is obtained by using the final bad block template to analyze, read from, and write to all blocks.

In this case, a bad column template represented by the final column set is a final bad column template that is relatively accurate, and a bad page template represented by the final page set is a final bad page template that is more accurate. Therefore, a relatively accurate bad block template can be obtained by replacing the bad column set in the initial bad block template with the final column set, replacing the bad page set in the initial bad block template with the final page set, and then obtaining the initial bad block template as the final bad block template. After all blocks are read from and written to with the final bad block template, the available capacity of flash can be obtained more precisely.

The implementation principle of this embodiment is as follows: NAND flash contains a plurality of blocks, where a block is equivalent to a matrix, a page is equivalent to a row in the matrix, and a column is equivalent to a column in the matrix. Several pages may be marked in the bad page template. These pages need to be skipped during data storage. Several columns may be marked in the bad column template. These columns need to be skipped during data storage. During analysis and detection of NAND flash, an initial bad page template and an initial bad column template are preset first. In this case, both the bad page template and the bad column template are empty sets. Then, bad pages are obtained from the pages, and the bad page template is updated. Subsequently, bad columns are obtained from the columns, and the bad column template is updated. The process of updating the bad page template and the bad column template in sequence is equivalent to updating the bad page template first when it is assumed that there is no bad column and then updating the bad column template based on the current bad page template. Because bad pages have been obtained at the beginning of the above process, some pages that have been damaged due to a physical property may be obtained first, to reduce an interference of these pages in evaluation of the columns. Therefore, the accuracy of the bad column template is improved, generation of false bad columns is reduced, and a risk that the available capacity of the NAND flash after analysis and detection is too low due to a too number of false bad columns is reduced.

In addition, the bad page template and the bad column template are updated in sequence, thereby updating the bad block template. In this embodiment, Update and iteration are performed on the bad block template repeatedly. Update of the bad page template and the update of the bad column template affect each other. The manner in which the accuracy of the bad column template is improved at the beginning can improve the overall accuracy of the bad block template in subsequent iteration and update.

There is no absolute clear definition of a bad page and a bad column, that is, neither the bad page nor the bad column has a completely accurate standard. Therefore, it is necessary to preset and update an error threshold, and then obtain a relatively accurate error threshold from a plurality of error thresholds as a relative standard for determining the bad page and/or the bad column. The error threshold includes a page error threshold and a column error threshold. Each time the page error threshold and/or the column error threshold are/is updated, the bad block template iterates once. Update of the page error threshold can make the bad page template iterate. By comparing the current bad page template with a bad page template before iteration, whether the bad page template before iteration is less affected by the column error threshold and meets the available capacity requirement can be evaluated. Finally, a relatively accurate bad page template is obtained. Similarly, the bad column template can iterate by updating the column error threshold.

The final bad block template can be obtained after obtaining the final bad page template and the final bad column template. In addition, after the available capacity of the current NAND flash can be obtained by writing, reading, and comparing all blocks via the final bad block template. After repeated iterations, the bad block template is relatively accurate. In one aspect, generation of false bad columns is reduced, and the available capacity of NAND flash after analysis and detection is increased. In another aspect, data stored in the NAND flash can be more stable.

A finally obtained bad column template is used for reading, writing, and comparison.

### Embodiment II

Referring to FIG. 6, in one embodiment, there is provided a detection system applied to intelligent analysis and detection for flash. Corresponding to the detection method in the above embodiment I, the detection system is applied to analysis and detection of the available capacity of NAND flash. The system includes an initial template establishment module 1, a template update module 2, a template iteration module 3, and a final template generation module 4. The functional modules are described in detail as follows:

The initial template establishment module 1 is configured to obtain a column set, a page set, and a block set including the column set and the page set, and preset a bad column set, a bad page set, an error threshold that can be updated for each iteration, and an initial bad block template including the bad column set and the bad page set.

The template update module 2 is configured to: according to a bad page selection strategy and a bad column selection strategy, alternately obtain bad page elements and bad column elements from the block set in sequence based on the error threshold, and alternately update the bad page set and the bad column set in sequence.

The template iteration module 3 is configured to: based on the bad column sets and the bad page sets corresponding to different error thresholds, update the error threshold according to a bad template iteration strategy, obtain a final column set from the bad column sets, and obtain a final page set from the bad page sets.

The final template generation module 4 is configured to obtain a final bad block template by updating the initial bad block template based on the final column set and the final page set.

### Embodiment III

In one embodiment, there is provided an intelligent terminal. The intelligent terminal includes a memory, a processor, and a computer program stored in the memory and executable by the processor. The memory stores training data, algorithms, filtering mechanisms, etc. in a training model. The processor is configured to provide capabilities of computing and controlling. The processor, when executing the computer program, implements the following steps:

step S1: obtaining a column set, a page set, and a block set including the column set and the page set, and presetting a bad column set, a bad page set, an error threshold that can be updated for each iteration, and an initial bad block template including the bad column set and the bad page set;

step S2: according to a bad page selection strategy and a bad column selection strategy, alternately obtaining bad page elements and bad column elements from the block set in sequence based on the error threshold, and alternately updating the bad page set and the bad column set in sequence;

step S3: based on the bad column sets and the bad page sets corresponding to different error thresholds, updating the error threshold according to a bad template iteration strategy, obtaining a final column set from the bad column sets, and obtaining a final page set from the bad page sets; and

step S4: obtaining a final bad block template by updating the initial bad block template based on the final column set and the final page set.

### Embodiment IV

In one embodiment, there is provided a computer-readable storage medium. The computer-readable storage medium stores a computer program that can be loaded by a processor and execute the above detection method. The computer program, when executed by the processor, implements the following steps:

step S1: obtaining a column set, a page set, and a block set including the column set and the page set, and presetting a bad column set, a bad page set, an error threshold that can be updated for each iteration, and an initial bad block template including the bad column set and the bad page set;

step S2: according to a bad page selection strategy and a bad column selection strategy, alternately obtaining bad page elements and bad column elements from the block set in sequence based on the error threshold, and alternately updating the bad page set and the bad column set in sequence;

step S3: based on the bad column sets and the bad page sets corresponding to different error thresholds, updating the error threshold according to a bad template iteration strategy, obtaining a final column set from the bad column sets, and obtaining a final page set from the bad page sets; and

step S4: obtaining a final bad block template by updating the initial bad block template based on the final column set and the final page set.

For example, the computer-readable storage medium may include: various media that can store program codes, such as a USB flash drive, a mobile hard disk, a read-only memory (ROM), a random access memory (RAM), a magnetic disk or an optical disk.

The above specific embodiments are merely preferred embodiments of the present application, and do not limit the protection scope of the present application. Therefore, any equivalent changes made based on the structure, shape, and principle of the present application shall fall within the protection scope of the present application.

1. A detection method applied to intelligent analysis and detection for flash, comprising:
step S1: obtaining a column set, a page set, and a block set comprising the column set and the page set, and presetting a bad column set, a bad page set, an error threshold that can be updated for each iteration, and an initial bad block template comprising the bad column set and the bad page set;
step S2: according to a bad page selection strategy and a bad column selection strategy, alternately obtaining bad page elements and bad column elements from the block set in sequence based on the error threshold, and alternately updating the bad page set and the bad column set in sequence;
step S3: based on the bad column sets and the bad page sets corresponding to different error thresholds, updating the error threshold according to a bad template iteration strategy, obtaining a final column set from the bad column sets, and obtaining a final page set from the bad page sets; and
step S4: obtaining a final bad block template by updating the initial bad block template based on the final column set and the final page set.

2. The method of claim 1, wherein step S2 comprises:
step S21: obtaining to-be-detected page subsets from the page set based on the bad column set according to a bad column interference elimination strategy, analyzing the to-be-detected page subsets in sequence based on the error threshold according to a bad page determining strategy, obtaining the bad page elements from the block set, and updating the bad page set based on the bad page elements; and
step S22: obtaining to-be-detected column subsets from the column set based on the bad page set according to a bad page interference elimination strategy, analyzing the to-be-detected column subsets in sequence based on the error threshold according to a bad column determining strategy, obtaining the bad column elements from the block set, and updating the bad column set based on the bad column elements.

3. The method of claim 2, wherein
step S1 further comprises: obtaining original column subsets and original page subsets, wherein the column set contains the original column subsets, and the page set contains the original page subsets;
step S21 comprises:
step S211: obtaining interference page subsets by mapping the bad column set to the original page subsets;
step S212: obtaining complements of the interference page subsets within corresponding original page subsets in sequence, and generating the to-be-detected page subsets; and
step S213: according to the bad page determining strategy, analyzing the to-be-detected page subsets in sequence based on the error threshold, obtaining the bad page elements from the block set, and updating the bad page set based on the bad page elements; and
step S22 comprises:
step S221: obtaining interference column subsets by mapping the bad page set to the original column subsets;
step S222: obtaining complements of the interference column subsets within corresponding original column subsets in sequence, and taking the complements as the to-be-detected column subsets; and
step S223: according to the bad column determining strategy, obtaining the bad column elements from the to-be-detected column subsets based on the error threshold, and updating the bad column set.

4. The method of claim 3, wherein
step S213 comprises:
step S2131: obtaining page error values of the to-be-detected page subsets in sequence according to an instruction error correction strategy;
step S2132: based on the error threshold and the page error values, according to a bad page screening strategy, sequentially selecting, from the to-be-detected page subsets, those subsets not meeting a page validity condition as invalid page subsets; and
step S2133: obtaining bad page elements based on the original page subsets corresponding to the invalid page subsets, and obtaining a set containing all the bad page elements as the bad page set; and
step S223 comprises:
step S2231: obtaining column error values of the to-be-detected column subsets in sequence according to the instruction error correction strategy;
step S2232: based on the error threshold and the column error values, according to a threshold comparison strategy, selecting, from the to-be-detected column subsets, those not meeting a column precision condition as invalid column subsets; and
step S2233: obtaining the bad column elements based on the original column subsets corresponding to the invalid column subsets, and obtaining a set containing all the bad column elements as the bad column set.

5. The method of claim 1, wherein
step S3 comprises:
step S31: establishing a template library used for storing to-be-compared templates corresponding to different error thresholds;
step S32: according to a template comparison strategy, determining whether complete error thresholds in the current template library have a minimum value meeting an available capacity condition, and if yes, performing step S34, and if no, performing step S33;
step S33: updating the error thresholds, updating the to-be-compared template based on the bad column set and the bad page set, storing the updated error thresholds and updated to-be-compared template into the template library, and returning to step S2; and
step S34: generating the final column set and the final page set based on the determining result.

6. The method of claim 5, wherein step S32 comprises:
step S321: determining whether the to-be-compared template exists in the current template library, and if yes, performing step S322, and if no, performing step S323;
step S322: determining whether the to-be-compared template meets an iteration termination condition, and if yes, performing step S34, and if no, performing step S33; and
step S323: obtaining a to-be-compared template containing the current bad column set and the current bad page set, and storing the to-be-compared template into the template library; and
step S34 further comprises: obtaining the bad column set in the to-be-compared template as the final column set, and obtaining the bad page set in the to-be-compared template as the final page set.

7. The method of claim 6, wherein step S322 comprises:
step S3221: presetting a column validity threshold, determining, based on the column validity threshold, whether the bad column set in the current to-be-compared template meets the available capacity condition, and if yes, performing step S3222, and if no, performing step S33;
step S3222: presetting a column iteration threshold, analyzing the to-be-compared template and the bad column set based on the column iteration threshold, determining whether the to-be-compared template meets a capacity change condition, and if yes, performing step S3223, and if no, performing step S33;
step S3223: presetting a page validity threshold, determining, based on the page validity threshold, whether the bad page set in the current to-be-compared template meets the available capacity condition, and if yes, performing step S3224, and if no, performing step S33; and
step S3224: presetting a page iteration threshold, analyzing the to-be-compared template and the bad page set based on the page iteration threshold, determining whether the to-be-compared template meets the capacity change condition, and if yes, performing step S34, and if no, performing step S33.

8. A detection system applied to intelligent analysis and detection for flash, comprising:
an initial template establishment module (1), configured to obtain a column set, a page set, and a block set comprising the column set and the page set, and preset a bad column set, a bad page set, an error threshold that can be updated for each iteration, and an initial bad block template comprising the bad column set and the bad page set;
a template update module (2), configured to: according to a bad page selection strategy and a bad column selection strategy, alternately obtain bad page elements and bad column elements from the block set in sequence based on the error threshold, and alternately update the bad page set and the bad column set in sequence;
a template iteration module (3), configured to: based on the bad column sets and the bad page sets corresponding to different error thresholds, update the error threshold according to a bad template iteration strategy, obtain a final column set from the bad column sets, and obtain a final page set from the bad page sets; and
a final template generation module (4), configured to obtain a final bad block template by updating the initial bad block template based on the final column set and the final page set.

9. An intelligent terminal, comprising a memory and a processor, wherein the memory stores a computer program, which can be loaded and executed by the processor to implement the detection method of claim 1.

10. A computer-readable storage medium, comprising a computer program, which can be loaded and executed by a processor to implement the detection method of claim 1.
